(19) United States
(12) Patent Application Publication
(10) Pub. No.: US 2024/0363799 A1
(43) Pub. Date: Oct. 31, 2024

(54) LIGHT-EMITTING DEVICE, LIGHT-EMITTING SUBSTRATE AND DISPLAY DEVICE

(71) Applicants: BOE MLED Technology Co., Ltd., Beijing (CN); BOE Technology Group Co., Ltd., Beijing (CN)

(72) Inventors: Yuanda LU, Beijing (CN); Shanwei YANG, Beijing (CN); Jiawei ZHAO, Beijing (CN); Zhijun XIONG, Beijing (CN); Yuanhao SUN, Beijing (CN); Xueqiao LI, Beijing (CN); Junjie MA, Beijing (CN)

(21) Appl. No.: 18/579,889

(22) PCT Filed: Sep. 29, 2021
(86) PCT No.: PCT/CN2021/121573

§ 371 Date: Jan. 17, 2024

(51) Int. Cl. H01L 33/20; H01L 33/38

(52) U.S. Cl. CPC H01L 33/20; H01L 33/38

(57) ABSTRACT

Provided are a light-emitting device, a light-emitting substrate and a display device. The light-emitting device includes: a substrate; a first semiconductor layer, the first semiconductor layer being located on one side of the substrate; a light-emitting layer, the light-emitting layer being located on the side of the first semiconductor layer facing away from the substrate; and a second semiconductor layer, the second semiconductor layer being located on the side of the light-emitting layer facing away from the first semiconductor layer.

### CROSS REFERENCE TO RELATED APPLICATIONS

The present disclosure is a US National Stage of International Application No. PCT/CN2021/121573, filed on Sep. 29, 2021, the entire contents of which are incorporated herein by reference.

### TECHNICAL FIELD

The present disclosure relates to the field of semiconductor technology, in particular to a light-emitting device, a light-emitting substrate and a display apparatus.

### BACKGROUND

As the key technology of display technology, the light emitting diode (LED) has become a trend in the display industry. How to improve the performance of products and enhance competitiveness of the products has become a direction that the upstream and downstream of the industry chain need to work together.

### SUMMARY

Embodiments of the present disclosure provide a light-emitting device, a light-emitting substrate and a display apparatus. The light-emitting device includes:
a substrate,
a first semiconductor layer, located at a side of the substrate;
a light-emitting layer, located at a side of the first semiconductor layer facing away from the substrate; and
a second semiconductor layer, located at a side of the light-emitting layer facing away from the first semiconductor layer;
where the first semiconductor layer is one of an N-type semiconductor layer and a P-type semiconductor layer, the second semiconductor layer is another one of the N-type semiconductor layer and the P-type semiconductor layer; an area of an orthographic projection of the second semiconductor layer on the substrate is smaller than an area of an orthographic projection of the light-emitting layer on the substrate, and the orthographic projection of the second semiconductor layer on the substrate is located within the orthographic projection of the light-emitting layer on the substrate.

In a possible implementation, the light-emitting device further includes a conductor layer located at a side of the second semiconductor layer facing away from the light-emitting layer, and a resistance of the conductor layer is smaller than a resistance of the second semiconductor layer; and
an area of an orthographic projection of the conductor layer on the substrate is approximately the same as the area of the orthographic projection of the second semiconductor layer on the substrate, and the orthographic projection of the conductor layer on the substrate approximately coincides with the orthographic projection of the second semiconductor layer on the substrate.

In a possible implementation, the light-emitting device further includes a third semiconductor layer located between the second semiconductor layer and the light-emitting layer, and a material of the third semiconductor layer is same as a material of the light-emitting layer; and
an area of an orthographic projection of the third semiconductor layer on the substrate is approximately the same as the area of the orthographic projection of the light-emitting layer on the substrate, and the orthographic projection of the third semiconductor layer on the substrate approximately coincides with the orthographic projection of the light-emitting layer on the substrate.

In a possible implementation, the third semiconductor layer is integrally formed with the second semiconductor layer.

In a possible implementation, a region where the orthographic projection of the third semiconductor layer on the substrate exceeds the second semiconductor layer is disposed around the second semiconductor layer.

In a possible implementation, the light-emitting layer includes a plurality of dielectric layers stacked in sequence; and a maximum thickness of a dielectric layer farthest from the first semiconductor layer is greater than maximum thicknesses of the remaining dielectric layers.

In a possible implementation, the maximum thickness of the dielectric layer farthest from the first semiconductor layer is 2 to 8 times the maximum thicknesses of the remaining dielectric layers.

In a possible implementation, the light-emitting layer includes a first region; and a second region located at a periphery of the first region;
the area of the orthographic projection of the second semiconductor layer on the substrate is approximately equal to an area of an orthographic projection of the first region on the substrate, and the orthographic projection of the second semiconductor layer on the substrate coincides with the orthographic projection of the first region on the substrate; and a thickness of the dielectric layer farthest from the first semiconductor layer at the second region is smaller than a thickness of the dielectric layer farthest from the first semiconductor layer at the first region.

In a possible implementation, the light-emitting device further includes an etching barrier layer located between the second semiconductor layer and the light-emitting layer, and an area of an orthographic projection of the etching barrier layer on the substrate is approximately same as the area of the orthographic projection of the light-emitting layer on the substrate, and the orthographic projection of the etching barrier layer on the substrate approximately coincides with the orthographic projection of the light-emitting layer on the substrate.

In a possible implementation, a rate at which the etching barrier layer is etched is smaller than a rate at which the second semiconductor layer is etched.

In a possible implementation, the first semiconductor layer includes: a first sub-portion; and a second sub-portion disposed outside the first sub-portion;
where an area of an orthographic projection of the first sub-portion on the substrate is approximately equal to the area of the orthographic projection of the light-emitting layer on the substrate, and the orthographic projection of the first sub-portion on the substrate approximately coincides with the orthographic projection of the light-emitting layer on the substrate;
the light-emitting device further includes: a first insulation layer located at a side of the second semiconductor layer facing away from the light-emitting layer, and a first connection electrode and a second connection electrode located at a side of the first insulation layer facing away from the second semiconductor layer; and
the first connection electrode is electrically connected with the second sub-portion through a first through hole penetrating through the first insulation layer, and the second connection electrode is electrically connected with the second semiconductor layer through a second through hole penetrating through the first insulation layer.

In a possible implementation, the second connection electrode is in direct contact with and electrically connected with the second semiconductor layer.

In a possible implementation, a center of the orthographic projection of the second semiconductor layer on the substrate coincides with a center of the orthographic projection of the first semiconductor layer on the substrate; the light-emitting device further includes: a bridging electrode located between the second semiconductor layer and the first insulation layer, and a second insulation layer located between the bridging electrode and the second semiconductor layer; wherein an end of the bridging electrode is electrically connected with the second semiconductor layer, and another end of the bridging electrode is electrically connected with the second connection electrode.

In a possible implementation, the light-emitting device is a blue light-emitting device or a green light-emitting device; the first semiconductor layer is an N-type semiconductor layer, and the second semiconductor layer is a P-type semiconductor layer.

In a possible implementation, the light-emitting device is a red light-emitting device, the first semiconductor layer is a P-type semiconductor layer, and the second semiconductor layer is an N-type semiconductor layer.

The embodiments of the present disclosure further provide a light-emitting substrate, including a plurality of the light-emitting device provided by the embodiments of the present disclosure.

The embodiments of the present disclosure further provide a display apparatus, including the light-emitting substrate provided by the embodiments of the present disclosure.

### BRIEF DESCRIPTION OF FIGURES

FIG. 1 is a schematic diagram of a display screen with poor uniformity at a low grayscale.

FIG. 2 is a schematic diagram of a model curve of internal quantum efficiency of a light-emitting diode.

FIG. 3 is a schematic diagram of a distribution of different light-emitting diodes at different current densities.

FIG. 4 is a schematic diagram of current-efficiency curves of light-emitting diodes with different light-emitting areas.

FIG. 5 is a comparative schematic diagram of different ratios of a light-emitting area to a perimeter.

FIG. 6 is a first schematic top view of a light-emitting device provided by an embodiment of the present disclosure.

FIG. 7 is a schematic cross-sectional view along a dotted line E1F1 in FIG. 6.

FIG. 8 is an enlarged schematic view of a dotted line coil X1 in FIG. 7.

FIG. 9 is a first schematic cross-sectional view of a light-emitting device provided by an embodiment of the present disclosure.

FIG. 10 is an enlarged schematic view of a dotted line coil X2 in FIG. 9.

FIG. 11 is a second schematic cross-sectional view of a light-emitting device provided by an embodiment of the present disclosure.

FIG. 12 is a third schematic cross-sectional view of a light-emitting device provided by an embodiment of the present disclosure.

FIG. 13 is a fourth schematic cross-sectional view of a light-emitting device provided by an embodiment of the present disclosure.

FIG. 14 is a fifth schematic cross-sectional view of a light-emitting device provided by an embodiment of the present disclosure.

FIG. 15 is a second schematic top view of a light-emitting device provided by an embodiment of the present disclosure.

FIG. 16 is a schematic cross-sectional view along a dotted line E2F2 in FIG. 15.

### DETAILED DESCRIPTION

In order to make the purpose, technical solutions and advantages of the embodiments of the present disclosure clearer, the technical solutions of the embodiments of the present disclosure will be clearly and completely described below in conjunction with drawings of the embodiments of the present disclosure. Apparently, the described embodiments are a part of the embodiments of the present disclosure, not all of the embodiments. Based on the embodiments of the present disclosure, all other embodiments obtained by those ordinarily skilled in the art without creative work shall fall within the scope of the present disclosure.

Unless otherwise defined, technical or scientific terms used in the present disclosure shall have the ordinary meanings as understood by those with ordinary skills in the art to which the present disclosure belongs. “First”, “second” and similar words used in the present disclosure do not indicate any order, quantity or importance, but are only used to distinguish different components. “Comprise” or “include” or other similar words mean that the element or item appearing before the word encompasses the element or item listed after the word and its equivalents, but does not exclude other elements or items. “Connecting” or “connected” or similar words are not limited to physical or mechanical connections, but may include electrical connections, whether direct or indirect. “Upper”, “lower”, “left”, “right”, etc., are merely used to indicate a relative position relation, which may also change accordingly when an absolute position of a described object changes.

To keep the following description of the embodiments of the present disclosure clear and concise, the detailed descriptions of known functions and components are omitted from the present disclosure.

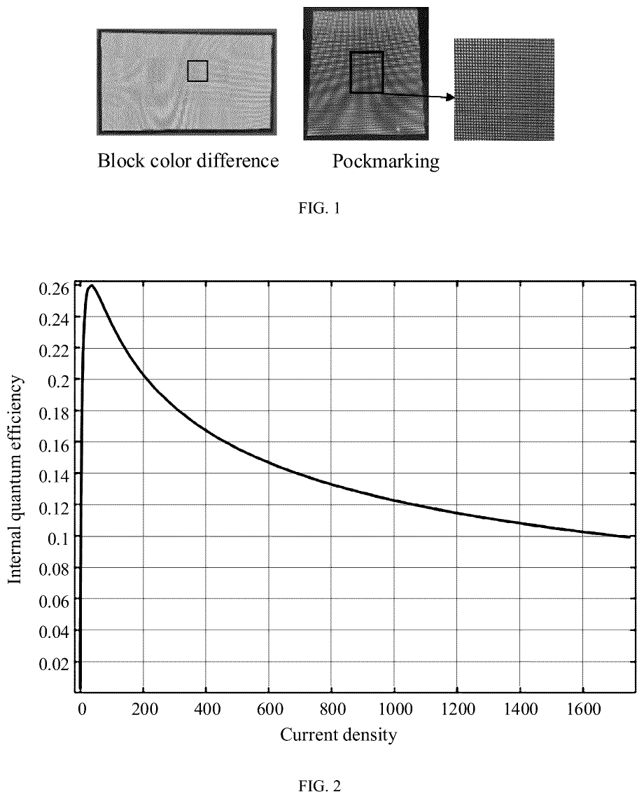

For display products, display effect is an eternal requirement. Light-emitting diodes used in the current light-emitting diode display are mainly used in passive display, and the realization of the grayscale is mainly regulated through the duty cycle, which means that the light-emitting diodes have been used with high current. Due to the accuracy of low grayscale and low cast, active display has become the development direction for subsequent display screens. The active display mainly uses current to adjust the grayscale. However, a light-emitting diode chip used as a light source has differences under different currents, especially in the case of low grayscale, the uniformity of the screen will be seriously reduced (as shown in FIG. 1). In order to improve the consistency of brightness of display products in the low gray grayscale and increase product competitiveness, how to solve the problem of low grayscale has become a bottleneck for the mass production of active driving solutions.

The curve shown in FIG. 2 is an ABC model curve of internal quantum efficiency of a light-emitting diode (LED), and its formula is:

$${η}_{IQE} = {η}_{INJ} \frac{{BN}^{2}}{AN + {BN}^{2} + {CN}^{3}} ,$$

where η_{IQE} is the internal quantum efficiency, η_{INJ} is carrier injection efficiency, A, B and Care three constants, A is mainly related to non-radiative recombination (mainly determined by defects) (10⁷˜10⁸), B is mainly related to radiative recombination (10⁻¹⁰˜10⁻¹²), C is mainly related to Auger recombination (10⁻³⁰), and N is the number of carriers. It can be seen that the value of N is relatively small when the current is small, and the efficiency of the LED chip is mainly determined by non-radiative recombination. In order to reduce the volatility caused by defects, it is necessary to operate the LED chip at a position where the value of N is relatively large, that is, operating in the high current density range.

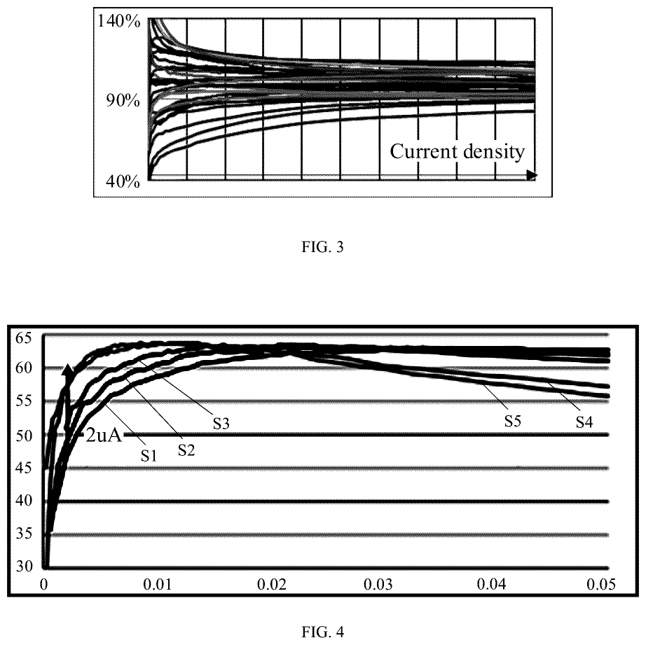

A distribution relationship of different light-emitting diodes at different current densities is shown in FIG. 3, where the abscissa represents a current density, the ordinate represents light-emitting efficiency, and multiple curves represent multiple light-emitting diodes respectively. As shown in FIG. 3, without reducing the size of a light-emitting diode chip, reducing an actual light-emitting area of the light-emitting diode to make the light-emitting diode be in the high current density range of the light-emitting diode when displaying in high grayscale and low grayscale, thus achieving the display consistency under the high grayscale and the grayscale, improving the effect of products, reducing the difficulty of process and materials, and promoting the commercialization process of mini light-emitting diode display products. Simultaneously, with reference to a schematic diagram of current-efficiency curve of light-emitting diodes with different light-emitting areas shown in FIG. 4, the abscissa represents a current, the ordinate represents light-emitting efficiency, and light-emitting areas of light-emitting diodes represented by curve S1, curve S2, curve S3, curve S4, and curve S5 decrease sequentially. As shown in FIG. 4, a position of the highest point of the current-efficiency curve shifts to the left after reducing the light-emitting area, that is, when it is used in the low current, the corresponding efficiency can be improved, thereby reducing power consumption.

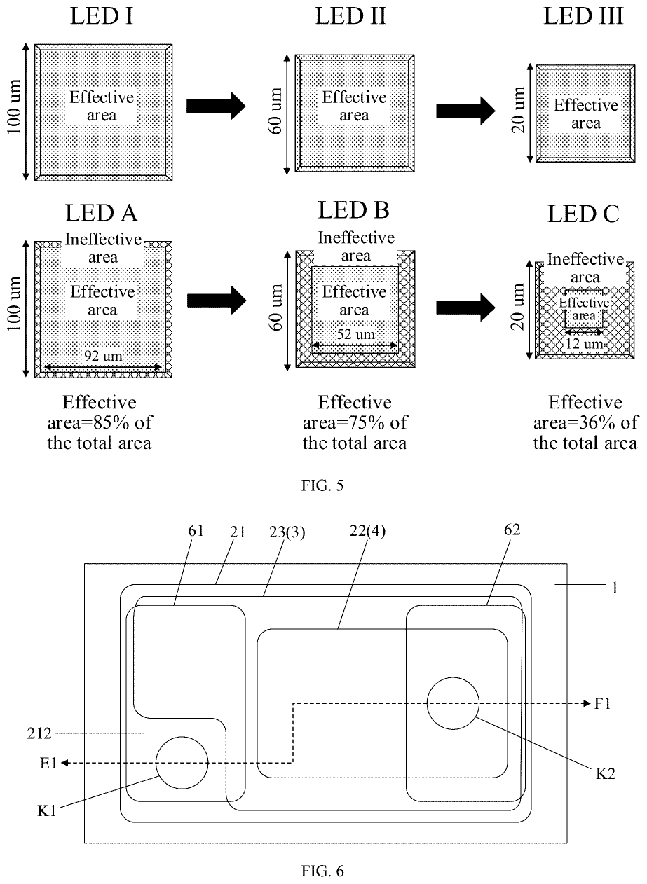

The method for reducing a light-emitting area in the related art is to directly etch a light-emitting layer (quantum well layer), as shown in FIG. 5. In FIG. 5, LED I, LED II and LED III represent effective areas (Good areas) of different quantum well areas when there is no edge effect influence, respectively; LED A, LED B and LED C are effective areas (Good areas) of corresponding quantum well areas when there is an edge effect, respectively. It can be seen that as a quantum well area shrinks, the distances (=4 um) of the areas affected by the edge effect are the same, a ratio of an actual effective area to the quantum well area will be reduced; when the quantum well area is reduced to less than 20 μm, the edge effect of the quantum well (generally intrusion ˜1 um) will rise sharply due to the greatly reduction of the ratio of the quantum well area to the perimeter. Therefore, how to reduce the effective light-emitting area under the premise of maintaining the area of the light-emitting layer, and how to improve the current density at low current while ensuring that the edge effect has little influence and to thereby improve the low grayscale performance, have become an urgent problem to be solved.

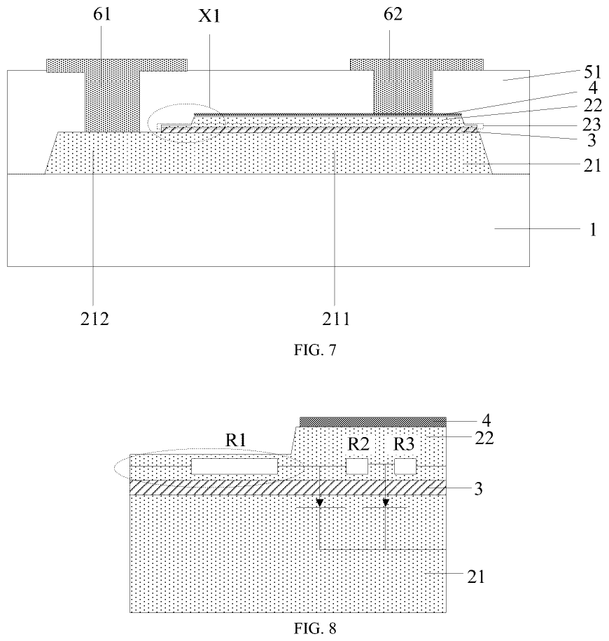

In view of this, referring to FIG. 6 and FIG. 7, FIG. 7 is a schematic cross-sectional view along a dotted line E1F1 in FIG. 6. Embodiments of the present disclosure provide a light-emitting device, including:
a substrate 1;
a first semiconductor layer 21, located at a side of the substrate 1;
a light-emitting layer 3, located at a side of the first semiconductor layer 21 facing away from the substrate 1; specifically, the light-emitting layer 3 may be a multiple quantum well (MQW) layer; and
a second semiconductor layer 22, located at a side of the light-emitting layer 3 facing away from the first semiconductor layer 21; where the first semiconductor layer 21 is one of an N-type semiconductor layer and a P-type semiconductor layer, and the second semiconductor layer 22 is another one of the N-type semiconductor layer and the P-type semiconductor layer; specifically, for example, for a blue or green light-emitting device, the first semiconductor layer 21 may be an N-type semiconductor layer, and the second semiconductor layer 22 may be a P-type semiconductor layer; for another example, for a red light-emitting device, the first semiconductor layer 21 may be a P-type semiconductor layer, and the second semiconductor layer 22 may be an N-type semiconductor layer; and an area of an orthographic projection of the second semiconductor layer 22 on the substrate 1 is smaller than an area of an orthographic projection of the light-emitting layer 3 on the substrate 1, and the orthographic projection of the second semiconductor layer 22 on the substrate 1 is located within the orthographic projection of the light-emitting layer 3 on the substrate 1.

In the embodiments of the present disclosure, the area of the orthographic projection of the second semiconductor layer 22 on the substrate 1 is smaller than the area of the orthographic projection of the light-emitting layer 3 on the substrate 1, and the orthographic projection of the second semiconductor layer 22 on the substrate 1 is located within the orthographic projection of the light-emitting layer 3 on the substrate 1. Under the condition that the area of the light-emitting layer 3 is kept constant, an effective light-emitting area of the light-emitting device can be reduced by reducing the area of the second semiconductor layer 22, so that the light-emitting device may have a higher current density under the condition that the influence of the edge effect is small and the supplied voltage is the same, to achieve the effect of uniform brightness of multiple light-emitting devices at the low grayscale.

In a possible implementation, as shown in FIG. 6 and FIG. 7, the light-emitting device further includes a conductive layer 4 located at a side of the second semiconductor layer 22 facing away from the light-emitting layer 3, and a resistance of the conductive layer 4 is smaller than a resistance of the second semiconductor layer 22. An area of the orthographic projection of the conductor layer 4 on the substrate 1 is approximately the same as an area of the orthographic projection of the second semiconductor layer 22 on the substrate 1, and the orthographic projection of the conductor layer 4 on the substrate 1 approximately coincides with the orthographic projection of the second semiconductor layer 22 on the substrate 1. Specifically, the conductive layer 4 may be a transparent electrode layer, and specifically, the material of the conductive layer 4 may include: indium tin oxide, indium zinc oxide, or zinc oxide doped with aluminum. Specifically, the area of the orthographic projection of the conductor layer 4 on the substrate 1 is approximately the same as the area of the orthographic projection of the second semiconductor layer 22 on the substrate 1, which can be understood that the ratio of the difference between the two to any one of them is less than 10%. The orthographic projection of the layer 4 on the substrate 1 approximately coincides with the orthographic projection of the second semiconductor layer 22 on the substrate 1, which can be understood that the coincidence degree of the two may be 80% to 100%. In the embodiments of the present disclosure, the lateral square resistance of the second semiconductor layer 22 (especially when the second semiconductor layer 22 is the P-type semiconductor layer) is relatively large (e.g., 10⁴-10⁵ Ω/□), and the conductive layer 4 is provided to make the conductive layer 4 (such as indium tin oxide, the square resistance is approximately 12 Ω/□) as the expansion layer, the expansion current can make more positive charges have channels to lead to the light-emitting layer 3 to combine with the negative charges of the first semiconductor layer 21 (N-type semiconductor layer) to emit light, thereby improving the light-emitting efficiency.

In a possible implementation, as shown in FIG. 6 and FIG. 7, the light-emitting device further includes a third semiconductor layer 23 located between the second semiconductor layer 22 and the light-emitting layer 3, and a material of the third semiconductor layer 23 is the same as the material of the second semiconductor layer 22; an area of an orthographic projection of the third semiconductor layer 23 on the substrate 1 is approximately the same as the area of the orthographic projection of the light-emitting layer 3 on the substrate 1. Specifically, as shown in FIG. 6 and FIG. 7, a region where the orthographic projection of the third semiconductor layer 23 on the substrate 1 exceeds the second semiconductor layer 22 is disposed around the second semiconductor layer 22. Specifically, the area of the orthographic projection of the third semiconductor layer 23 on the substrate 1 is approximately the same as the area of the orthographic projection of the light-emitting layer 3 on the substrate 1, which can be understood as the ratio of the difference between the two to any one of them is less than 10%; and the orthographic projection of the third semiconductor layer 23 on the substrate 1 roughly coincide with the orthographic projection of the light-emitting layer 3 on the substrate 1, which can be understood that the coincidence degree of the two may be 80% to 100%.

Specifically, the orthographic projection of the third semiconductor layer 23 on the substrate 1 roughly coincides with the orthographic projection of the light-emitting layer 3 on the substrate 1. Specifically, the third semiconductor layer 23 and the second semiconductor layer 22 can be formed integrally. Specifically, a corresponding semiconductor material layer can be grown at one time during epitaxial growth, and after etching, the second semiconductor layer 22 and the third semiconductor layer 23 are formed. The principle of reducing the effective light-emitting area can be shown in FIG. 8, where the FIG. 8 is an enlarged schematic diagram of a dotted line circle X1 in FIG. 7. In a condition that the light-emitting device is a blue or green light-emitting device, and the second semiconductor Layer 22 is a P-type semiconductor layer, since the high lateral resistance of the P-type semiconductor layer, it is necessary to use the conductor layer 4 as an expansion layer to expand the current, so that as many positive charges as possible can have channels to pass through the quantum well layer, so that the positive charges can compound with the negative charges injected into the N-type layer to emit light. But after reducing the area of the P-type semiconductor layer, since there is no conductor layer 4 in the upper layer and the thickness of the upper layer is thinned (the thinned region is shown by the dotted circle in FIG. 8), the lateral resistance of a portion of the P-type semiconductor layer that has been etched is much greater than that of other portion of the P-type semiconductor layer that is not etched, so as to reduce the actual light-emitting area and achieve high current density at low current. Moreover, the semiconductor remaining in the thinned region can provide effective protection for the light-emitting layer 3. The actual effect can be seen in an equivalent circuit in FIG. 8, the value of R1 is determined by the lateral resistance of the P-type semiconductor layer, and the values of R2 and R3 are determined by the lateral resistance of the conductor layer 4. R1 is much larger than R2 and R3, and the current mainly travels from the region provided with an expansion layer (conductor layer 4), thereby effectively reducing the light-emitting area. The red light-emitting device is similar to the blue or green light-emitting device, but the lateral resistance of the N-type semiconductor layer in the red light-emitting device is small (for example, the resistance of the N-type semiconductor material GaP is about 100 Ω/□), and there is no need to set an extension layer. In fact, reducing the area of the N-type semiconductor layer can also improve the brightness uniformity of different light-emitting devices at low grayscale, but compared with the blue or green light-emitting devices provided with the conductor layer 4, the effect is smaller.

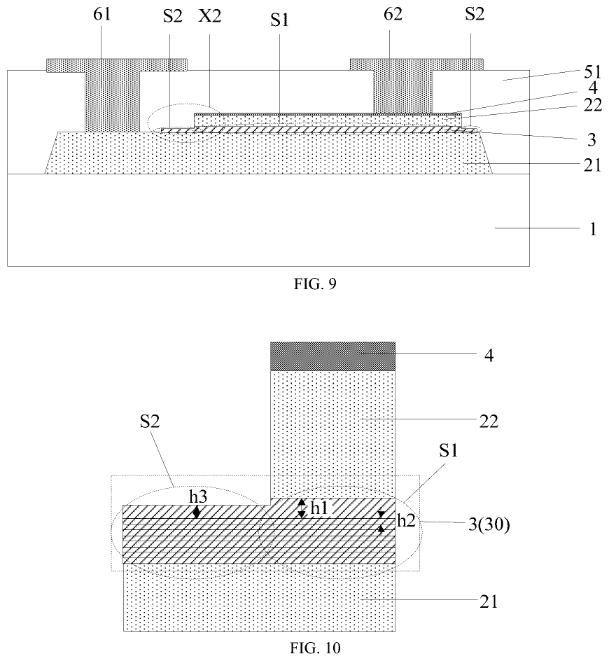

In a possible implementation, as shown in FIG. 9 and FIG. 10, where FIG. 10 is an enlarged schematic view of a dotted line circle X2 in FIG. 9, the light-emitting layer 3 includes multiple dielectric layers 30 stacked sequentially, and the maximum thickness h1 of the dielectric layer 30 farthest from the first semiconductor layer 21 is greater than the maximum thicknesses h2 of the remaining dielectric layers 30. In the embodiments of the present disclosure, by increasing the thickness of the dielectric layer 30 farthest from the first semiconductor layer 21, it is possible to avoid the problem that the light-emitting layer 3 may be etched through due to a process error and a thin light-emitting layer when etching the second semiconductor layer 22 in the case of patterning the second semiconductor layer 22 to make the area of the orthographic projection of the second semiconductor layer 22 on the substrate 1 be smaller than the area of the orthographic projection of the light-emitting layer 3 on the substrate 1.

Specifically, as shown in FIG. 10, a portion where the orthographic projection of the dielectric layer 30 farthest from the first semiconductor layer 21 on the substrate 1 exceeds the second semiconductor layer 22 may be partially etched, as such, the position of the maximum thickness of the dielectric layer 30 farthest from the first semiconductor layer 21 can be a position where the orthographic projection of the dielectric layer overlaps with the second semiconductor layer 22, as shown in FIG. 10; the remaining dielectric layers 30 can be uniform in thickness at each position, therefore, the maximum thicknesses of the remaining dielectric layers 30 may be the thickness at any position of the remaining dielectric layers 30.

Specifically, the maximum thickness of the dielectric layer 30 farthest from the first semiconductor layer 21 may be 2 to 8 times the maximum thickness(es) of the remaining dielectric layers.

Specifically, the light-emitting layer 3 may include a plurality of first sub-dielectric layers and a plurality of second sub-dielectric layers that are alternately arranged in sequence. For example, the light-emitting device is a blue light-emitting device, the material of the first sub-dielectric layer is gallium nitride (GaN), the material of the second sub-dielectric layer is indium gallium nitride (InGaN), and the dielectric layer 30 farthest from the first semiconductor layer 21 is the first sub-dielectric layer. Specifically, the controllability of etching the light-emitting layer 3 can be increased by increasing the thickness of the GaN layer (for example, the thickness of the GaN farthest from the first semiconductor layer 21 is usually 10 nm to 20 nm, in the embodiments of the present disclosure, the GaN layer farthest from the first semiconductor layer 21 can be set to have a thickness of 50 nm-100 nm), so that the etching process directly etches to the light-emitting layer 3, relative to the light-emitting layer, by reducing the area of the second semiconductor layer 22, the area of the second semiconductor layer 22 is smaller than the area of the light-emitting layer 3, thus reducing the effective light-emitting area. Specifically, for example, the light-emitting device is a green light-emitting device, the material of the first sub-dielectric layer is gallium nitride (GaN), the material of the second sub-dielectric layer is indium gallium nitride (InGaN), and the dielectric layer 30 farthest from the first semiconductor layer 21 is the second sub-dielectric layer, specifically the thickness of the InGaN layer can be increased (for example, the thickness of the InGaN layer farthest from the first semiconductor layer 21 is usually 10 nm-20 nm, in the embodiments of the present disclosure, the thickness of the InGaN layer farthest from the first semiconductor layer 21 can be set to be 50 nm-100 nm). Specifically, for example, the light-emitting device is a red light-emitting device, the material of the first sub-dielectric layer is AlₓGa_{y}In_{1-x-y}P, the material of the second sub-dielectric layer is AlₐGa_{b}In_{1-a-b}P, and the dielectric layer 30 farthest from the first semiconductor layer 21 is AlGaInP layer, specifically the thickness of AlGaInP layer can be increased (for example, the thickness of the AlGaInP layer farthest from the first semiconductor layer 21 is usually 10 nm-20 nm, in the embodiments of the present disclosure, the thickness of the AlGaInP layer farthest from the first semiconductor layer 21 can be set to be 50 nm-100 nm).

Specifically, FIG. 9 and FIG. 10 are schematic illustrations by taking the light-emitting device without the third semiconductor layer 23 as an example. Specifically, while thickening the dielectric layer 30 farthest from the first semiconductor layer 21 in the light-emitting layer 3 of the light-emitting device, a third semiconductor layer 23 may also be provided to further prevent the light-emitting layer 3 from being etched through.

In a possible implementation, as shown in FIG. 9 or FIG. 10, the light-emitting layer 3 includes a first region S1, and a second region S2 located at the periphery of the first region S1, and the area of the orthographic projection of the second semiconductor layer 22 on the substrate 1 is approximately equal to an area of an orthographic projection of the first region S1 on the substrate 1, and the orthographic projection of the second semiconductor layer 22 on the substrate 1 coincides with the orthographic projection of the first region S1 on the substrate 1; a thickness h3 of the dielectric layer 30 farthest from the first semiconductor layer 21 at the second region S2 is smaller than a thickness h1 of the dielectric layer 30 farthest from the first semiconductor layer 21 at the first region for S1.

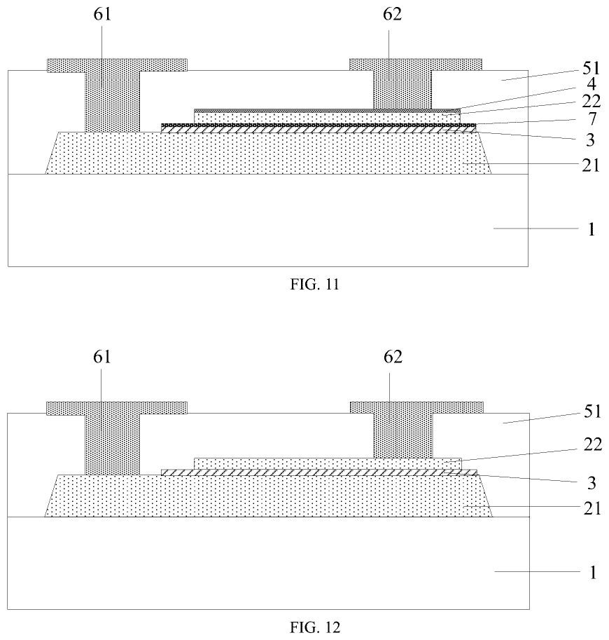

In a possible implementation, as shown in FIG. 11, the light-emitting device further includes an etching barrier layer 7 located between the second semiconductor layer 22 and the light-emitting layer 3, and an area of an orthographic projection of the etching barrier layer 7 on the substrate 1 is approximately the same as the area of the orthographic projection of the light-emitting layer 3 on the substrate 1, and the orthographic projection of the etching barrier layer 7 on the substrate 1 approximately coincides with the orthographic projection of the light-emitting layer 3 on the substrate 1. In the embodiments of the present disclosure, through the etching barrier layer 7 between the second semiconductor layer 22 and the light-emitting layer 3, it is also possible to avoid the problem that the light-emitting layer 3 may be etched through due to a process error and a thin light-emitting layer when etching the second semiconductor layer 22 after patterning the second semiconductor layer 22 to make the area of the orthographic projection of the second semiconductor layer 22 on the substrate 1 be smaller than the area of the orthographic projection of the light-emitting layer 3 on the substrate 1.

Specifically, FIG. 11 is a schematic illustration of an example where the light-emitting device is not provided with the third semiconductor layer 23. Specifically, when the light-emitting device is provided with the etching barrier layer 7, the third semiconductor layer 23 may also be provided to further prevent the light-emitting layer 3 from being etched through. Specifically, while setting the third semiconductor layer 23, the etching barrier layer 7 may be specifically provided between the third semiconductor layer 23 and the light-emitting layer 3.

Specifically, a rate at which the etching barrier layer 7 is etched is lower than a rate at which the second semiconductor layer 22 is etched. In this way, when patterning the second semiconductor layer 22, the etching rate of the etching liquid to the etching barrier layer 7 is much lower than that of the second semiconductor layer 22, so that the etching process can be well controlled to avoid damage to the light-emitting layer 3 caused by excessive etching. Specifically, when the light-emitting device is a blue or green light-emitting device, the material of the etching barrier layer 7 may be AlN.

In a possible implementation, as shown in FIGS. 7 to 11, the first semiconductor layer 21 includes a first sub-portion 211, and a second sub-portion 212 disposed outside the first sub-portion 211. An area of an orthographic projection of the first sub-portion 211 on the substrate 1 is approximately equal to the area of the orthographic projection of the light-emitting layer 3 on the substrate 1, and the orthographic projection of the first sub-portion 211 on the substrate 1 approximately coincides with the orthographic projection of the light-emitting layer 3 on the substrate 1. The light-emitting device further includes a first insulation layer 51 located at a side of the second semiconductor layer 22 facing away from the light-emitting layer 3, and a first connection electrode 61 and a second connection electrode 62 that are located at a side of the first insulation layer 51 facing away from the second semiconductor layer 22. The first connection electrode 61 is electrically connected with the second sub-portion 212 through a first through hole K1 penetrating through the first insulation layer 51, and the second connection electrode 62 is electrically connected with the second semiconductor layer 22 through a second through hole K2 penetrating through the first insulation layer 51. Specifically, as shown in FIG. 7, for example, a shape of the first semiconductor layer 21 may be a rectangle, a shape of the first sub-portion 211 may be a rectangle with one corner missing, and by setting the second sub-portion 212 in a shape with one corner missing, it is possible to achieve electrically connecting the first semiconductor layer 21 via the first connection electrode 61 at the second subpart 212 that is not blocked by the light-emitting layer 3.

Specifically, the electrical connection between the second connection electrode 62 and the second semiconductor layer 22 may be that the second connection electrode 62 and the second semiconductor layer 22 are electrically connected through the conductor layer 4, as shown in FIG. 7; or the two are directly contacted electrically, for example, referring to FIG. 12, the second connection electrode 62 may be in direct contact with and electrically connected with the second semiconductor layer 22. Specifically, for example, the light-emitting device is a red light-emitting device, a conductor layer may not be required, and the second connection electrode 62 is in direct contact with the second semiconductor layer 22 for electrical connection. By reducing the area of the second semiconductor layer 22 relative to the light-emitting layer 3, the brightness uniformity of different light-emitting devices at the low grayscale can also be improved. Compared with the blue or green light-emitting devices provided with the conductive layer 4, the effect is smaller. Specifically, for another example, the light-emitting device is a blue or green light-emitting device, the second connection electrode 62 may also be directly contacted with the second semiconductor layer 22 for electrical connection, by reducing the area of the second semiconductor layer 22 relative to the light-emitting layer 3, the brightness uniformity of different light-emitting devices at the low grayscale can also be improved.

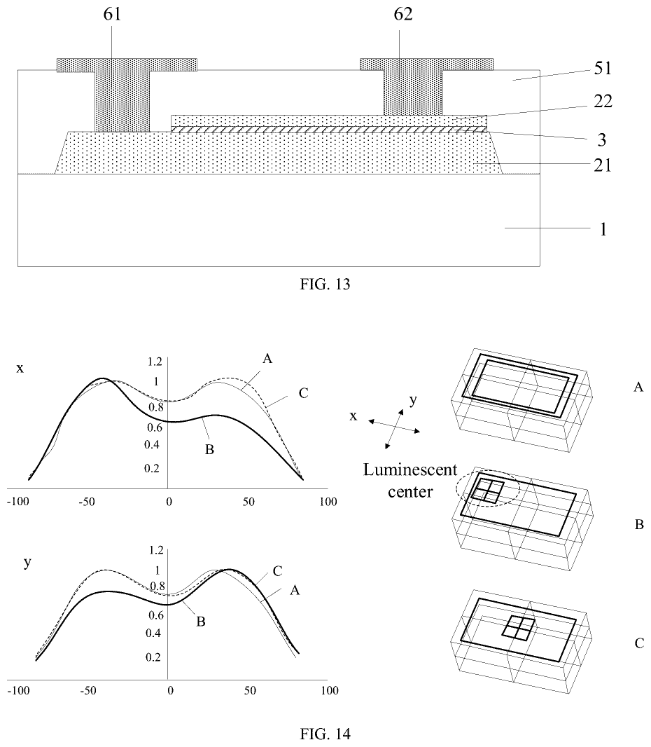

In a possible implementation, as shown in FIG. 13, the second connection electrode 62 may be in direct contact with and electrically connected with the second semiconductor layer 22, and the area of the orthographic projection of the second semiconductor layer 22 on the substrate 1 is approximately the same as the area of the orthographic projection of the light-emitting layer 3 on the substrate 1, and the orthographic projection of the second semiconductor layer 22 on the substrate 1 approximately coincides with the orthographic projection of the light-emitting layer 3 on the substrate 1. Specifically, for example, when the light-emitting device is a blue or green light-emitting device, by not providing a conductor layer, the carriers injected into the light-emitting layer 3 by the second connection electrode 62 can be mainly located in a region where the second connection electrode 62 is located, which reduces the effective light-emitting area of the light-emitting device, so that the brightness uniformity of different light-emitting devices at the low grayscale can also be improved.

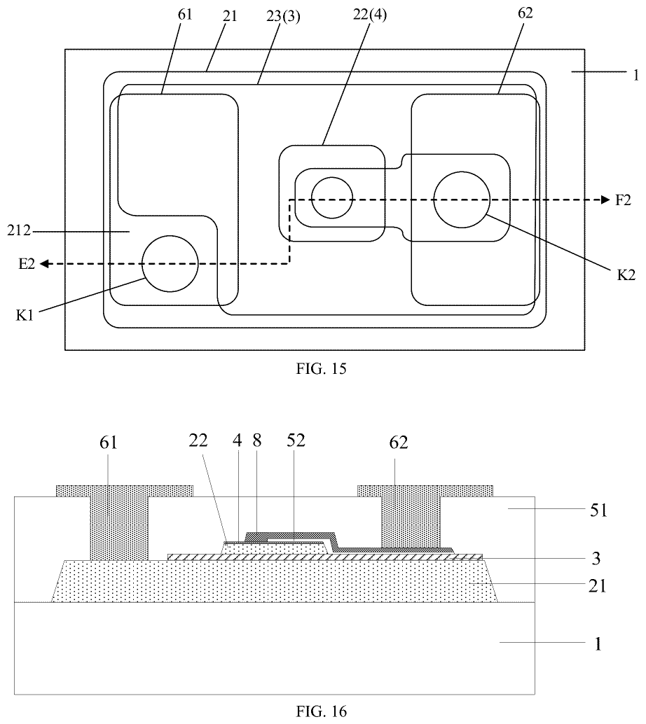

Specifically, in the case of increasing the current density, the effective light-emitting area needs to be smaller and smaller, and to a certain extent (generally <50 um on one side), a through-hole needs to be set below an electrode due to a position limitation of the electrode (for example, the first connection electrode 61, and the second connection electrode 62), which restricts a light-emitting position to be located at an edge of the light-emitting device. As shown in FIG. 14, A represents a position and light emitting curve when an effective light-emitting area is not reduced, B represents a position and light emitting curve when an effective light emitting area is reduced and is not located in a central region of the light-emitting device, and C represents a position and light emitting curve when an effective light-emitting area is reduced and is located in a central region of the light-emitting device. In the present disclosure, the inventor, through optical simulation, found that shapes of the light emitting curves of the light-emitting device will be different when the light-emitting region is located at different positions. In order to solve this problem, it is necessary to adjust the light-emitting position to a geometric center of the LED. As such, specifically, refer to FIG. 15 and FIG. 16, where FIG. 16 is a schematic cross-sectional view along a dotted line E2F2 in FIG. 15, a center of the orthographic projection of the second semiconductor layer 22 on the substrate 1 coincides with a center of the orthographic projection of the first semiconductor layer 21 on the substrate 1. The light-emitting device further includes: a bridging electrode 8 between the second semiconductor layer 22 and the first insulation layer 51, and a second insulation layer 52 between the bridging electrode 8 and the second semiconductor layer 22; one end of the bridging electrode 8 is electrically connected with the second semiconductor layer 22, and the other end of the bridging electrode 8 is electrically connected with the second connection electrode 62. In the embodiments of the present disclosure, by setting the center of the orthographic projection of the second semiconductor layer 22 on the substrate 1 to coincide with the center of the orthographic projection of the first semiconductor layer 21 on the substrate 1, the problem of affecting normal display caused by changing the shape of the light emitting curve of the light-emitting device resulting in an abnormal wavelength band of the emitting light can be avoided when the effective light-emitting area is reduced.

Specifically, the center of the orthographic projection of the second semiconductor layer 22 on the substrate 1 may be the geometric center of the orthographic projection of the second semiconductor layer 22 on the substrate 1, and the center of the orthographic projection of the first semiconductor layer 21 on the substrate 1 may be the geometric center of the orthographic projection of the first semiconductor layer 21 on the substrate 1.

Specifically, for example, as shown in FIG. 15 and FIG. 16, the orthographic projection of the second semiconductor layer 22 on the substrate 1 is a rectangle, then the center of the orthographic projection of the second semiconductor layer 22 on the substrate 1 is the center of the rectangle; and the orthographic projection of the first semiconductor layer 21 on the substrate 1 is a rectangle, then the center of the orthographic projection of the first semiconductor layer 21 on the substrate 1 is the center of the rectangle. Alternatively, the orthographic projection of the second semiconductor layer 22 on the substrate 1 is a circle, then the center of the orthographic projection of the second semiconductor layer 22 on the substrate 1 is the center of the circle; and the orthographic projection of the first semiconductor layer 21 on the substrate 1 is a circle, then the center of the orthographic projection of the first semiconductor layer 21 on the substrate 1 is the center of the circle.

Specifically, one end of the bridging electrode 8 is electrically connected with the second semiconductor layer 22, i.e. the one end of the bridging electrode 8 may be in direct contact with and electrically connected with the second semiconductor layer 22, or the one end of the bridging electrode 8 may be electrically connected with the second semiconductor layer 22 through the conductor layer 4, as shown in FIG. 16. The other end of the bridging electrode 8 is electrically connected to the second connection electrode 62, i.e., the other end of the bridging electrode 8 may be in direct contact with and electrically connected with the second connection electrode 62.

Specifically, in the embodiments of the present disclosure, the light-emitting device may be a light-emitting diode, and the light-emitting diode may specifically be a mini light-emitting diode.

Based on the same inventive concept, embodiments of the present disclosure further provide a light-emitting substrate, which includes a plurality of light-emitting devices as provided in the embodiments of the present disclosure.

Based on the same inventive concept, embodiments of the present disclosure further provide a display apparatus, including the light-emitting substrate as provided in the embodiments of the present disclosure.

In the embodiments of the present disclosure, the area of the orthographic projection of the second semiconductor layer 22 on the substrate 1 is smaller than the area of the orthographic projection of the light-emitting layer 3 on the substrate 1, and the orthographic projection of the second semiconductor layer 22 on the substrate 1 is located within the orthographic projection of the light-emitting layer 3 on the substrate 1, while keeping the area of the light-emitting layer 3 constant, the effective light-emitting area of the light-emitting device can be reduced by reducing the area of the second semiconductor layer 22, so that the light-emitting device can have a higher current density under the condition that the influence of the edge effect is small and the supplied voltage is the same, to achieve the effect of uniform brightness of multiple light-emitting devices at the low grayscale.

While preferred embodiments of the present disclosure have been described, additional changes and modifications can be made to these embodiments by those skilled in the art once the basic inventive concept is appreciated. Therefore, it is intended that the appended claims be construed to cover the preferred embodiments and all changes and modifications which fall within the scope of the present disclosure.

Apparently, those skilled in the art can make various changes and modifications to the embodiments of the present disclosure without departing from the spirit and scope of the embodiments of the present disclosure. In this way, if the modifications and variations of the embodiments of the present disclosure fall within the scope of the claims of the present disclosure and equivalent technologies, the present disclosure also intends to include these modifications and variations.

1. A light-emitting device, comprising:
a substrate;
a first semiconductor layer, located at a side of the substrate;
a light-emitting layer, located at a side of the first semiconductor layer facing away from the substrate; and
a second semiconductor layer, located at a side of the light-emitting layer facing away from the first semiconductor layer;
wherein the first semiconductor layer is one of an N-type semiconductor layer and a P-type semiconductor layer, the second semiconductor layer is another one of the N-type semiconductor layer and the P-type semiconductor layer; an area of an orthographic projection of the second semiconductor layer on the substrate is smaller than an area of an orthographic projection of the light-emitting layer on the substrate, and the orthographic projection of the second semiconductor layer on the substrate is located within the orthographic projection of the light-emitting layer on the substrate.

2. The light-emitting device according to claim 1, further comprising a conductor layer located at a side of the second semiconductor layer facing away from the light-emitting layer, and a resistance of the conductor layer is smaller than a resistance of the second semiconductor layer; and
an area of an orthographic projection of the conductor layer on the substrate is approximately same as the area of the orthographic projection of the second semiconductor layer on the substrate, and the orthographic projection of the conductor layer on the substrate approximately coincides with the orthographic projection of the second semiconductor layer on the substrate.

3. The light-emitting device according to claim 1, further comprising a third semiconductor layer located between the second semiconductor layer and the light-emitting layer, and a material of the third semiconductor layer is same as a material of the light-emitting layer; and
an area of an orthographic projection of the third semiconductor layer on the substrate is approximately same as the area of the orthographic projection of the light-emitting layer on the substrate, and the orthographic projection of the third semiconductor layer on the substrate approximately coincides with the orthographic projection of the light-emitting layer on the substrate.

4. The light-emitting device according to claim 3, wherein the third semiconductor layer is integrally formed with the second semiconductor layer.

5. The light-emitting device according to claim 3, wherein a region where the orthographic projection of the third semiconductor layer on the substrate exceeds the second semiconductor layer is disposed around the second semiconductor layer.

6. The light-emitting device according to claim 1, wherein the light-emitting layer comprises a plurality of dielectric layers stacked in sequence; and
a maximum thickness of a dielectric layer farthest from the first semiconductor layer is greater than maximum thicknesses of remaining dielectric layers.

7. The light-emitting device according to claim 6, wherein the maximum thickness of the dielectric layer farthest from the first semiconductor layer is 2 to 8 times the maximum thicknesses of the remaining dielectric layers.

8. The light-emitting device according to claim 6, wherein the light-emitting layer comprises:
a first region; and
a second region located at a periphery of the first region;
wherein the area of the orthographic projection of the second semiconductor layer on the substrate is approximately equal to an area of an orthographic projection of the first region on the substrate, and the orthographic projection of the second semiconductor layer on the substrate coincides with the orthographic projection of the first region on the substrate; and
a thickness of the dielectric layer farthest from the first semiconductor layer at the second region is smaller than a thickness of the dielectric layer farthest from the first semiconductor layer at the first region.

9. The light-emitting device according to claim 1, further comprising an etching barrier layer located between the second semiconductor layer and the light-emitting layer, and an area of an orthographic projection of the etching barrier layer on the substrate is approximately same as the area of the orthographic projection of the light-emitting layer on the substrate, and the orthographic projection of the etching barrier layer on the substrate approximately coincides with the orthographic projection of the light-emitting layer on the substrate.

10. The light-emitting device according to claim 9, wherein a rate at which the etching barrier layer is etched is smaller than a rate at which the second semiconductor layer is etched.

11. The light-emitting device according to claim 1, wherein the first semiconductor layer comprises:
a first sub-portion; and
a second sub-portion disposed outside the first sub-portion;
wherein an area of an orthographic projection of the first sub-portion on the substrate is approximately equal to the area of the orthographic projection of the light-emitting layer on the substrate, and the orthographic projection of the first sub-portion on the substrate approximately coincides with the orthographic projection of the light-emitting layer on the substrate;
wherein the light-emitting device further comprises:
a first insulation layer located at a side of the second semiconductor layer facing away from the light-emitting layer; and
a first connection electrode and a second connection electrode which are located at a side of the first insulation layer facing away from the second semiconductor layer;
wherein the first connection electrode is electrically connected with the second sub-portion through a first through hole penetrating through the first insulation layer, and the second connection electrode is electrically connected with the second semiconductor layer through a second through hole penetrating through the first insulation layer.

12. The light-emitting device according to claim 11, wherein the second connection electrode is in direct contact with and electrically connected with the second semiconductor layer.

13. The light-emitting device according to claim 10, wherein a center of the orthographic projection of the second semiconductor layer on the substrate coincides with a center of an orthographic projection of the first semiconductor layer on the substrate;
the light-emitting device further comprises: a bridging electrode located between the second semiconductor layer and the first insulation layer, and a second insulation layer located between the bridging electrode and the second semiconductor layer; wherein an end of the bridging electrode is electrically connected with the second semiconductor layer, and another end of the bridging electrode is electrically connected with a second connection electrode.

14. The light-emitting device according to claim 1, wherein the light-emitting device is a blue light-emitting device or a green light-emitting device;
the first semiconductor layer is the N-type semiconductor layer, and the second semiconductor layer is the P-type semiconductor layer.

15. The light-emitting device according to claim 1, wherein the light-emitting device is a red light-emitting device, the first semiconductor layer is the P-type semiconductor layer, and the second semiconductor layer is the N-type semiconductor layer.

16. A light-emitting substrate, comprising a plurality of light-emitting devices, wherein each of the plurality of light-emitting devices comprises:
a substrate;
a first semiconductor layer, located at a side of the substrate;
a light-emitting layer, located at a side of the first semiconductor layer facing away from the substrate; and
a second semiconductor layer, located at a side of the light-emitting layer facing away from the first semiconductor layer;
wherein the first semiconductor layer is one of an N-type semiconductor layer and a P-type semiconductor layer, the second semiconductor layer is another one of the N-type semiconductor layer and the P-type semiconductor layer; an area of an orthographic projection of the second semiconductor layer on the substrate is smaller than an area of an orthographic projection of the light-emitting layer on the substrate, and the orthographic projection of the second semiconductor layer on the substrate is located within the orthographic projection of the light-emitting layer on the substrate.

17. A display apparatus, comprising the light-emitting substrate according to claim 16.

18. The light-emitting substrate according to claim 16, wherein each of the plurality of light-emitting devices further comprises a conductor layer located at a side of the second semiconductor layer facing away from the light-emitting layer, and a resistance of the conductor layer is smaller than a resistance of the second semiconductor layer; and
an area of an orthographic projection of the conductor layer on the substrate is approximately same as the area of the orthographic projection of the second semiconductor layer on the substrate, and the orthographic projection of the conductor layer on the substrate approximately coincides with the orthographic projection of the second semiconductor layer on the substrate.

19. The light-emitting substrate according to claim 16, wherein each of the plurality of light-emitting devices further comprises a third semiconductor layer located between the second semiconductor layer and the light-emitting layer, and a material of the third semiconductor layer is same as a material of the light-emitting layer; and
an area of an orthographic projection of the third semiconductor layer on the substrate is approximately same as the area of the orthographic projection of the light-emitting layer on the substrate, and the orthographic projection of the third semiconductor layer on the substrate approximately coincides with the orthographic projection of the light-emitting layer on the substrate.

20. The light-emitting substrate according to claim 19, wherein the third semiconductor layer is integrally formed with the second semiconductor layer.
